(19) United States
(12) Patent Application Publication
(10) Pub. No.: US 2026/0227241 A1
(43) Pub. Date: Aug. 6, 2026

(54) THERMAL DETECTOR OF ELECTROMAGNETIC RADIATION COMPRISING A THERMOMETER DIODE

(71) Applicant: COMMISSARIAT A L'ENERGIE ATOMIQUE ET AUX ENERGIES ALTERNATIVES, Paris (FR)

(72) Inventors: Charlotte LATARGEZ, Grenoble Cedex 09 (FR); Mélanie LE COCQ, Grenoble Cedex 09 (FR); Abdelkader ALIANE, Grenoble Cedex 09 (FR); Valérie GOUDON, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/530,742

(22) Filed: Feb. 5, 2026

(30) Foreign Application Priority Data
Feb. 6, 2025 (FR) FR2501203

(51) Int. Cl. G01J 5/24; G01J 5/20; G01K 7/01; H10D 8/50

(52) U.S. Cl. CPC G01J 5/24; G01K 7/015; H10D 8/50; G01J 2005/204

(57) ABSTRACT

The invention relates to a thermal detector comprising a thermal transducer which comprises a diode thermally coupled to an absorber. The diode comprises a defective region, a spacer layer and a charge layer. The charge layer has a concentration of majority carriers at least 100 times greater than that of the spacer layer. The defective region and the spacer layer are in contact with the charge layer on either side of the latter. The defective region comprises crystalline defects and has a gap energy strictly lower than that of the charge layer. The charge layer and the defective region are located on the same side of the junction. A readout circuit is configured to reverse bias the diode, so as to extend the zone of space charges until it reaches the defective region, and read a dark current of the diode.

### TECHNICAL FIELD

The field of the invention is that of thermal detectors of electromagnetic radiation, for example infrared or terahertz, comprising a thermal transducer formed by a diode.

### PRIOR ART

Thermal detectors of electromagnetic radiation, for example infrared or terahertz, can comprise a micro-bridge suspended above a readout substrate and thermally insulated from the latter. Arranged at least partly on the micro-bridge, the thermal detector comprises an absorber of the electromagnetic radiation to be detected, and a thermal transducer, thermally coupled to the latter. The thermal transducer has an electrical property that varies according to its temperature rise. Such a thermal transducer can comprise a thermistor (for example containing vanadium oxide or amorphous silicon), a diode (p-n or p-i-n junction), or a metal-oxide-semiconductor field-effect transistor (or MOSFET).

An important parameter, characteristic of the sensitivity of a thermal detector, is the noise equivalent power (or NEP). The NEP corresponds to the detection limit of the thermal detector. It should be reduced. For this, it is possible to increase the thermal insulation of the micro-bridge. For example, when it is suspended above the readout substrate by thermal insulation arms, the NEP is lower when the arms are longer and/or thinner. It is also possible to increase the absorption of the electromagnetic radiation by the absorber, or the sensitivity of the thermal transducer.

When the thermal transducer implements a thermistor, its sensitivity is characterized by the Temperature Coefficient of Resistance (or TCR). This is the relative variation in its electric resistance according to a variation in its temperature. For a thermistor containing vanadium oxide, the TCR can typically reach 2 to 3%/K in absolute value. However, this type of material is difficult to integrate.

Comparable or even slightly higher sensitivities can be achieved with a MOSFET or a diode used as a thermal transducer. In this case, the sensitivity is characterized by the Temperature Coefficient of Current (or TCC). This is the relative change in the electric current passing through the transistor or the diode according to a variation in its temperature. A TCC of 5 to 8%/K can be achieved with a forward-biased diode of the p-n junction type, depending on certain operating conditions. However, these types of thermal transducers generally suffer from high 1/f noise.

### DISCLOSURE OF THE INVENTION

The goal of the invention is to at least partly overcome the disadvantages of the prior art, and more particularly to propose a thermal detector of electromagnetic radiation having improved sensitivity and having low measurement noise, in particular low 1/f noise.

For this, the object of the invention is a thermal detector of electromagnetic radiation, comprising: an absorber configured to heat up by absorption of the electromagnetic radiation; a thermal transducer comprising a diode thermally coupled to the absorber, the diode comprising a defective region, a spacer layer and a charge layer, all three interposed between an anode and a cathode of the diode, such that: the charge layer has a concentration of majority carriers at least 100 times greater than a concentration of majority carriers in the spacer layer, the defective region and the spacer layer are in contact with the charge layer on either side of the latter, the defective region comprises crystalline defects and has a gap energy strictly lower than a gap energy of the charge layer, the charge layer and the defective region are located on the same side of the diode, relative to a junction of the diode.

The thermal detector further comprises a readout circuit configured to reverse bias the diode to a bias voltage Vd strictly lower than its breakdown voltage in absolute value, so as to extend a zone of space charges of the diode until it reaches the defective region, and read a dark current of the diode when it is biased to the bias voltage V_{D}.

Some preferred, yet non-limiting, aspects of this thermal detector are as follows.

The defective region can be unintentionally doped.

A semiconductor region or layer is unintentionally doped when its doping results solely from residual impurities of the process. For clarification purposes, it is known that such a non-intentionally doped region or layer may have a dopant species concentration less than or equal to 1E16 at/cm³.

The diode can comprise an unintentionally doped small-gap layer in contact with the charge layer, and the defective region and the anode can be two separated regions of the small-gap layer. The defective region can comprise dislocations.

The diode can comprise a structured interface that can separate the charge layer from the small-gap layer, so as to confine the dislocations.

The defective region can comprise a number of dislocations per cm² between 10⁵ and 10¹².

The difference between a gap energy of the charge layer and a gap energy of the defective region can be greater than 0.38 eV.

The spacer layer and the charge layer can be made of silicon. The small-gap layer can be made of germanium or an alloy of silicon and germanium.

The concentration of majority carriers in the charge layer and its arrangement can be such that no impact ionization occurs in the small-gap layer and in the spacer layer when the diode is biased to the bias voltage Vd.

The readout circuit can be arranged in and/or on a readout substrate of the thermal detector, the thermal detector can be such that it comprises a micro-bridge suspended above the readout substrate and onto which the diode and the absorber can be fastened on either side thereof, and the diode can be electrically connected to the readout circuit by a portion of the absorber.

The thermal detector can comprise a reflector forming with the absorber a quarter-wave optical cavity for the electromagnetic radiation inside which the diode can be arranged, and the diode can be such that the gap energy of the defective region is strictly greater than the energy of the most energetic photon of the electromagnetic radiation.

The invention also relates to a global-shutter thermal image sensor comprising an array of thermal detectors according to any one of the preceding features. The readout circuit of each thermal detector can be part of a common readout circuit of the image sensor, if applicable the common readout circuit can be configured to read a dark current of each diode of between 0.1 nA and 10 nA.

The invention also relates to a method for manufacturing a thermal detector according to any one of the preceding features, comprising a step of forming the defective region implementing a heteroepitaxy of a first layer on a second layer, respectively made of a first semiconductor material and a second semiconductor material, having different lattice parameters so as to create dislocations in a sublayer of the first layer intended to accommodate the defective region.

The manufacturing method can comprise a step of homoepitaxy of the second layer on a growth layer comprising in-situ doping of a sublayer of the second layer intended to house the charge layer.

The growth layer can be intended to house the cathode or the anode. The manufacturing method can comprise a step of doping the growth layer prior to the step of homoepitaxy.

The manufacturing method can comprise a step of structuring the second layer prior to the heteroepitaxy.

### BRIEF DESCRIPTION OF THE DRAWINGS

Other aspects, aims, advantages and features of the invention will become more apparent upon reading the following detailed description of preferred embodiments thereof, provided by way of non-limiting example, and made with reference to the appended drawings wherein:

FIG. 1A is a schematic cross-sectional view of a first example of a diode essential to the implementation of a thermal detector according to the invention;

FIG. 1B is a schematic cross-sectional view of a second example of a diode essential to the implementation of a thermal detector according to the invention;

FIG. 2 is a schematic cross-sectional view of a thermal detector according to the invention integrating a diode according to the first example or the second example;

FIG. 3A is a graph giving TCC measurement results obtained with a diode according to the first example, as a function of the bias voltage Vd applied to its terminals;

FIG. 3B is a graph giving the TCC measurement results of FIG. 3A, as a function of the dark current passing through the diode;

FIG. 3C is a graph giving results of measurement of the power spectral density of the noise at 10 Hz obtained with the diode of FIG. 3A, as a function of the dark current passing through it;

FIG. 4A is a graph giving TCC simulation results obtained with diodes made of different materials, as a function of the bias voltage Vd applied to their terminals;

FIG. 4B is a graph giving the TCC simulation results of FIG. 4A, as a function of the dark current passing through the diodes;

FIGS. 5A to 5D are schematic cross-sectional views of steps of a method for manufacturing a first part of a thermal detector according to the invention, comprising a readout circuit;

FIGS. 6A to 6K are schematic cross-sectional views of steps of a method for manufacturing a second part of the thermal detector according to the invention, comprising a diode according to the first or the second example;

FIGS. 7A to 7J are schematic cross-sectional views of final steps of a method for manufacturing the thermal detector according to the invention.

### DETAILED DISCLOSURE OF SPECIFIC EMBODIMENTS

In the figures and in the following description, the same references represent identical or similar elements. Furthermore, the different elements are not represented to scale so as to favor clarity of the figures. Moreover, the different embodiments and alternatives are not mutually exclusive and could be combined together. Unless stated otherwise, the terms “substantially”, “about”, and “in the range of” mean within a 10% margin, and preferably within a 5% margin. Moreover, the terms “between . . . and . . . ” and equivalents mean that the bounds are included, unless specified otherwise.

The invention relates to a thermal detector of electromagnetic radiation, for example infrared or terahertz. This can be electromagnetic radiation in the far infrared spectrum (or LWIR, for “Long Wave Infra Red”), for example between 8 μm and 14 μm. The thermal detector is preferably intended to operate at ambient temperature.

The thermal detector comprises a readout circuit, an absorber and a thermal transducer. The thermal transducer comprises a diode reverse biased by the readout circuit. The diode is thermally coupled to the absorber, for example by thermal conduction. The absorber is configured to heat up by absorption of the electromagnetic radiation. The diode has a particular architecture that promotes the appearance of a dark electric current I_{dark} Of the generation-recombination type dominated by a Shockley-Read-Hall recombination current, known by the acronym SRH. The readout circuit reads the dark current which is an increasing function of the temperature of the diode, and consequently of the intensity of the electromagnetic radiation to be detected.

The architecture of the diode is composed in particular of a charge layer, a defective region and a spacer layer. The defective region and the spacer layer are in contact with the charge layer, on either side of the latter. Doping conditions of the charge layer and of the intermediate layer allow to position, in operation, the defective region in the space charge zone, and thus increase an electric field internal to the diode at the level thereof, without generating a phenomenon of impact ionization. The defective region has crystalline defects. The latter are centers of generation of electric charges which are collected at the terminals of the diode under the effect of the internal electric field, thus generating an SRH dark current highly dependent on the temperature of the diode. The reading of this dark current thus allows to obtain a high sensitivity of the thermal transducer and consequently to decrease the NEP of the thermal detector.

At first glance, the trap-assisted SRH current in a semiconductor material having a gap energy E_{g} is proportional to T 3/2e−Eₐ/k_{B}T, where Ea is the activation energy which is approximately equal to Eg/2, T is the temperature in Kelvin and KB is the Boltzmann constant. Thus, the value of the SRH current and its relative variation as a function of a variation in temperature depend on the gap energy.

In the context of the invention, the gap energy of the defective region is strictly lower than that of the charge layer. Thus, the dark current is high enough to be read by the readout circuit, in particular with a low signal-to-noise ratio—even higher when the gap energy of the defective region is low-without compromising on the value of the TCC—even greater when the gap energy of the charge layer is high. The thermal transducer therefore has increased sensitivity with respect to thermal transducers according to the prior art.

As a result, the defective region and the charge layer are made of different semiconductor materials. In an advantageous embodiment of the invention, this difference is exploited to obtain defects of the defective region by an epitaxial growth generating dislocations.

In the description, two elements are “thermally coupled” when a thermal conduction path connects the two elements so that heat can be efficiently transferred from one to the other. The two elements can be in physical contact with one another. They can alternatively or in addition be separated from one another by a medium having low thermal resistance, for example less than or equal to 1E3K/W. Equivalently or in addition, the heat can be transferred from one to the other by convection and/or radiation.

Specific embodiments will be described relating to a thermal detector comprising an absorber and a thermal transducer, intended for the detection of an infrared electromagnetic radiation, for example in the far infrared. However, these embodiments can be adapted to other thermal detectors, for example to a thermal detector sensitive in the terahertz range. If applicable, the absorber can comprise an antenna connected or electrically coupled to an impedance-matched resistive load, the resistive load being thermally coupled to the thermal transducer. Other adaptations may be necessary, for example such as the addition of one or more transparent materials to adjust the height of a quarter-wave cavity between the absorber and the readout substrate.

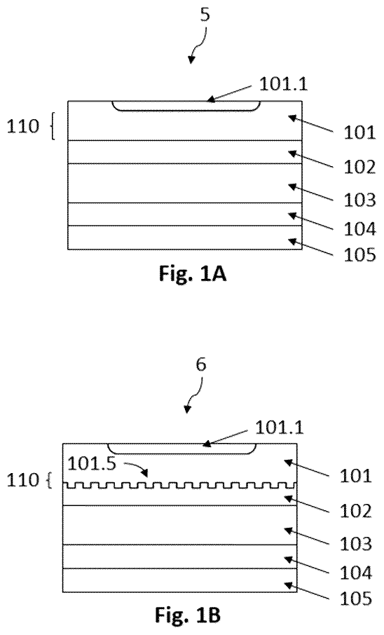

FIGS. 1A and 1B are respective cross-sectional views of a first and a second example of a diode 5, 6 belonging to the thermal transducer 1. These examples will be described in relation to a specific combination of conductivities associated with the doped zones or layers, with it being understood that the combination can be reversed without going beyond the scope of the invention. Thus, for each example, all the P-doped zones can be N-doped and all the N-doped zones can be P-doped, provided that the type of conductivity of all the doped zones is changed.

In FIG. 1A, the diode 5 comprises, in successive, distinct and parallel planes, a small-gap layer 101, a charge layer 102, a spacer layer 103, a transition layer 104 and a cathode 105. Here, each of these layers has two opposite faces, flat and parallel to a main plane of the diode 5. The charge layer 102 is in physical contact with the small-gap layer 101 and the spacer layer 103. The transition layer 104 is optional. It is in contact with the spacer layer 103 and the cathode 105 when it is present, otherwise the cathode 105 is directly in contact with the spacer layer 103.

Layer means, here and for the remainder of the description, an expanse consisting of one or more sublayers of a material, the thickness of which along an axis z is less, for example ten times, or even twenty times, than its longitudinal width and length dimensions in a plane (x, y) perpendicular to the axis z. A layer can be structured on one of its faces. When it consists of a plurality of sublayers, the sublayers can be made of different materials. The sublayer(s) extend in planes substantially parallel to the plane (x, y). When a layer has a property, it is understood that when it consists of a plurality of sublayers, all the sublayers have the same property, unless explicitly stated otherwise. As an example, unless further specified, a layer made of metal or made of a semiconductor or amorphous material can comprise several sublayers, all respectively made of metal, made of a semiconductor material, or amorphous. A layer can be conformal, which means that it extends over a surface, for example not flat, and that it conforms to this surface.

In FIG. 1A, the layers 101 to 104 and the cathode 105 are shown with substantially aligned sides, without this being necessary. As an example, the cathode 105 can extend parallel to the main plane beyond the other layers, for example to make an electric contact used to bias the diode 5 rest thereon.

The diode 5 comprises a heterojunction, that is to say a p-n or p-i-n junction separating two semiconductor regions having opposite electrical conductivities and different gap energies. Here, the cathode 105 and the transition layer 104 are N-doped. The charge layer 102 is P-doped. The spacer layer 103 is preferably unintentionally doped or weakly P-doped. It has a concentration of majority carriers 100 times lower than a concentration of majority carriers in the charge layer 102, preferably 200 times lower.

The small-gap layer 101 comprises a defective region 110. The defective region 110 comprises defects acting as centers of generation-recombination of charge carriers. It extends parallel to the main plane, in physical contact with the charge layer 102. It is made of a first substantially crystalline semiconductor material. The defects can be of several types for example such as interstitial atoms, impurities, grain joints, etc. Advantageously, these are dislocations, for example resulting from an epitaxy of the defective region 110 on the charge layer 102, as is the case in the first and second examples of a diode 5, 6.

The density of defects in the defective region 110 can be increased to increase the dark current I_{dark}. It is low enough to contain the 1/f noise. In the case in which the defects are dislocations, the density of dislocations can be between 10⁵ dislocations/cm² and 10¹² dislocations/cm². The density of dislocations can be measured by any known techniques, for example by transmission electron microscopy or by topographic XRD measurement. Dislocations present in a material can be exposed by polishing it and by immersing it in an etching solution that reacts substantially with the defects present in the material.

The defective region 110 is unintentionally doped, or weakly P-doped. It has a gap energy lower than the respective gap energies of the charge layer 102 and of the spacer layer 103. The charge layer 102 and the spacer layer 103 are made of a second semiconductor material different from the first semiconductor material. In this example, the cathode 105 and the transition layer 104 are also made of the second semiconductor material, here silicon.

The small-gap layer 101 further comprises a P-doped zone forming an anode 101.1 of the diode 5. It has a concentration of majority carriers strictly greater than a concentration of majority carriers in the defective region 110. Here, the defective region 110 and the anode 101.1 form a partition of the small-gap layer 101, that is to say they are separated and the union thereof consists of the small-gap layer 101.

The anode 101.1 is flush with an upper face of the small-gap layer 101, opposite to the charge layer 102 and the cathode 105. On the upper face, it occupies a surface area sufficient to house an electric contact allowing to bias the diode 5. It can occupy the entire upper face. It advantageously has a concentration of majority carriers sufficient to allow the creation of an ohmic contact. In this first example, the defective region 110 comprises threading dislocations, which can extend from the charge layer 102 to the upper face, and optionally extend into the anode 101.1.

Here, the small-gap layer 101 is integrally made of the first semiconductor material. Since the latter is different from the second semiconductor material forming the charge layer 102, it is possible that atomic elements coming from one or the other layer have diffused on either side of an interface separating them, for example during their creation. In this example, the first material is germanium or a silicon-germanium alloy. When the charge layer 102 is made of silicon, a thin silicon-germanium layer can be present at the interface resulting from the diffusion of germanium or silicon atoms coming from one and/or the other layer.

The transition layer 104 has a concentration of majority charge carriers strictly lower than a concentration of majority charge carriers in the cathode 105. The cathode 105 has for example a concentration of dopant atoms sufficient to create an ohmic contact. When it has a substantially constant concentration of dopant atoms in planes parallel to the main plane, it can be obtained by in-situ doping during an epitaxial growth of the cathode 105. The presence of the transition layer 104 can be particularly advantageous in this case, in particular for adjusting the internal electric field of the diode 5.

In planes parallel to the main plane, the stack consisting of the transition 104, spacer 103, charge 102 and small-gap 101 layers can have cross-sections with square, rectangular, circular or elliptical borders. Their cross-sections are for example superimposed according to a view perpendicular to the main plane of the diode 5. The cross-sections can have one, several or all of their dimensions less than or equal to 40 μm, to 15 μm, or even less than or equal to 10 μm.

As an example, when the cathode 105, the transition 104, spacer 103, charge 102 layers are made of silicon, and the small-gap layer 101 is made of germanium, the cathode 105 can have a thickness of 50 nm and a concentration of dopant atoms of the donor type equal to 1E19 at/cm³. The transition layer 104 can have a thickness of 50 nm and a concentration of dopant atoms of the donor type equal to 1E17 at/cm³. The spacer layer 103 can have a thickness between 50 nm and 100 nm, and a concentration of dopant atoms less than or equal to 1E15 at/cm³. The charge layer 102 can have a thickness between 10 nm and 100 nm, for example equal to 50 nm, and a concentration of dopant atoms of the acceptor type between 1E17 at/cm³ and 1E18 at/cm³, for example equal to 2E17 at/cm³. The small-gap layer 101 can have a thickness between 50 nm and 100 nm. The defective region 110 can have a concentration of dopant atoms less than or equal to 1E16 at/cm³.

The diode 6 of FIG. 1B differs from that of FIG. 1A in that it comprises a structured interface 101.5 separating the charge layer 102 from the small-gap layer 101, that is to say that the charge layer 102 has a structured upper face conforming to a structured lower face of the defective region 110 and of the small-gap layer 101. The structuring of the structured interface 101.5 is here capable of confining dislocations of the defective region 110 in a region close to the small-gap layer 101 close to the structured interface 101.5, that is to say that the defective region 110 has a height measured perpendicularly to the main plane strictly smaller than the height of the defective region 110 of the first example of a diode 5 of FIG. 1A. The defective region 110 height can be measured by transmission electron microscopy. The small-gap layer 101 can consequently comprise an intermediate crystalline region, substantially devoid of crystalline defects separating the defective region 110 from the anode 101.1. The intermediate crystalline region has a concentration of dopant atoms strictly lower than the concentration of dopant atoms in the anode, here substantially equal to the concentration of dopant atoms in the defective region 110. The anode 101.1 and the defective region 110 are two separated regions of the small-gap layer 101.

The structured interface 101.5 comprises a repetition of patterns, for example periodic, and preferably over substantially the entire structured interface 101.5. Several type of patterns or combinations of patterns can be suitable for structuring the structured interface 101.5. These can be parallel lines, a grid, a set of holes or pads. The patterns can have heights measured perpendicularly to the main plane between 25 nm and 50 nm. Their heights are preferably greater than or equal to half the thickness of the charge layer 102. All the patterns preferably have the same height. The patterns can be periodic, for example holes or trenches made in the charge layer 102. If applicable, the period can be between 1 μm and 1.5 μm. Alternatively, the structured interface 101.5 can correspond to a surface roughness of the charge layer 102.

In operation, the confinement of the dislocations to the vicinity of the structured interface 101.5 allows to concentrate the centers of generation-recombination of electric charges inside the space charge zone, and thus increase the SRH electric current.

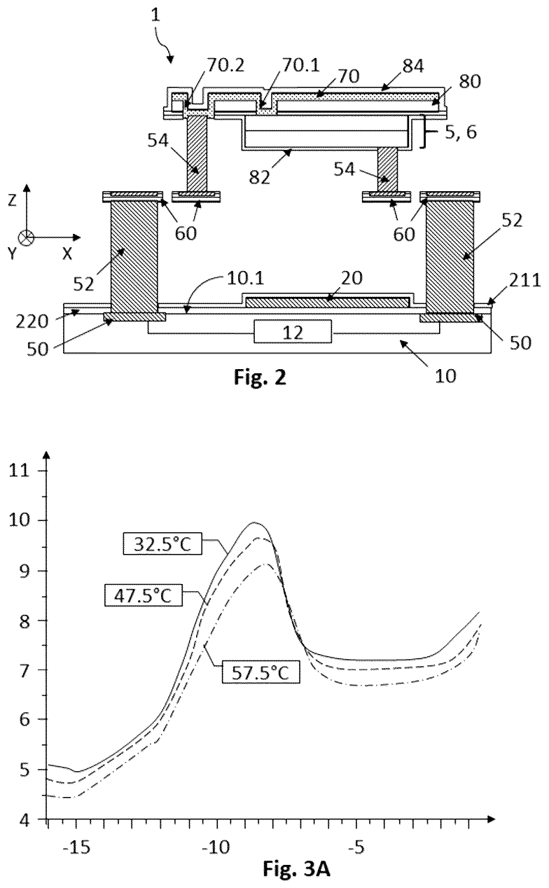

Now, in connection to FIG. 2, an example of a thermal detector 1 according to the invention will be described. The latter comprises a diode formed by a heterojunction, symbolized by a horizontal solid line in the cross-sectional view of FIG. 2. The diode is an element essential to the operation of a thermal transducer of the thermal detector 1. Here, this is a diode 5, 6 according to the first example or the second example, represented in a simplified manner so as not to overload the drawing.

The thermal detector 1 comprises a readout substrate 10, a micro-bridge 80 suspended above the readout substrate 10 by two thermal insulation arms 60 of the thermal detector 1. The micro-bridge 80 is arranged facing an upper face 10.1 of the readout substrate 10. The thermal detector 1 comprises a readout circuit 12. In this example, the readout circuit 12 is arranged in and/or on the readout substrate 10.

Here and for the remainder of the description, an orthogonal three-dimensional right-handed coordinate system (X, Y, Z) attached to the readout substrate 10 is defined, wherein the axes X and Y form a plane parallel to the upper face 10.1 of the readout substrate 10, the axis X being oriented in the cutting plane of FIG. 2, and wherein the axis Z is oriented substantially orthogonally to the upper face 10.1, from the readout substrate 10 to the micro-bridge 80. In the rest of the description, the terms “vertical” and “vertically” are understood as relating to an orientation substantially parallel to the axis Z, and the terms “horizontal” and “horizontally” as relating to an orientation substantially parallel to the plane (X, Y). Moreover, the terms “lower” and “upper” are defined as relating to an increasing positioning when moving away from the readout substrate 10 in the +Z direction. The term “lateral” refers to an orientation substantially parallel to the axis Z.

The thermal insulation arms 60 are disposed in a plane parallel to the plane (X, Y), between the micro-bridge 80 and the readout substrate 10. Each thermal insulation arm 60 has a proximal end fastened to the micro-bridge 80 by a connection pillar 54, and a distal end resting on an anchoring pillar 52. Each thermal insulation arm 60 is electrically conductive. It has a cross-section and a length allowing to thermally insulate the micro-bridge 80 and the diode 5, 6 from the readout substrate 10. The smaller the surface area of the transverse cross-section and/or the larger the length of a thermal insulation arm 60, the better the thermal insulation of the micro-bridge 80. To increase the length, it is for example possible to give each thermal insulation arm 60 the shape of a coil as is the case in FIG. 2. The anchoring pillars 52 and the connection pillars 54 are shown here in the same cutting plane, but other configurations are possible. When the thermal detector 1 is an element of an array of thermal detectors, an anchoring pillar 52 can be shared with a neighboring thermal detector.

Each thermal insulation arm 60 can have an electrically conductive metal core, surrounded by an insulating sheath, for example made of a material resistant to an etching used to remove a sacrificial material on which the micro-bridge 80 rests during an intermediate step of a manufacturing method. In this example, the core is made of titanium nitride (TiN) and the sheath is made of amorphous silicon, capable of resisting etching by hydrofluoric acid in the vapor phase.

The thermal detector 1 comprises an optional reflector 20. The reflector 20 is capable of reflecting the electromagnetic radiation to be detected. It is for example made of an aluminum-copper alloy (AICu). It extends on the upper face 10.1, in contact with an optional spacer layer 220. The spacer layer 220 is in physical contact with the upper face 10.1 and extends over substantially the entire surface thereof, with the exception of zones facing connection pads 50 of the readout circuit 12. Each connection pillar 54 is electrically connected to a connection pad 50 via a thermal insulation arm 60 and an anchoring pillar 52. The spacer layer 220 can for example be a layer for passivating or protecting the readout substrate 10. The readout substrate 10 with or without the spacer layer 220 can be provided by a semiconductor chip foundry, before or after cutting.

The reflector 20 is covered by an optional first protective layer 211. The first protective layer 211 extends here over the entire reflector 20 and over the entire spacer layer 220. This is a conformal layer conforming to the lateral sides of the reflector 20. It can be made of a material resistant to an etching of the sacrificial material. The spacer layer 220 is made of silicon oxide here. The first protective layer 211 can be made of amorphous silicon or alumina.

The anchoring pillars 52 pass completely through the first protective layer 211 and the spacer layer 220 in a region of the thermal detector 1 in which they are in contact, until they reach a corresponding connection pad 50.

The diode 5, 6 is arranged on the micro-bridge 80 on one side of the micro-bridge 80 facing the upper face 10.1 of the readout substrate 10 and the reflector 20. The main plane of the diode 5, 6 and the micro-bridge 80 extend parallel to the plane (X, Y). The diode 5, 6 is arranged here so that the cathode 105 is interposed between the small-gap layer 101 and the micro-bridge 80. A symmetrical arrangement according to a symmetry orthogonal to the plane (X, Y) is also possible.

The thermal detector 1 comprises an absorber 70. The absorber 70 extends on an upper face of the micro-bridge 80 opposite to the diode 5, 6. It is in contact with the micro-bridge 80. The absorber 70 is a conformal metal layer conforming to vias passing completely through the micro-bridge 80. A first electric contact zone 70.1 of the absorber 70 coats the walls of a via passing through the micro-bridge 80 and the cathode 105 of the diode 5, 6, thus ensuring electric contact with the cathode 105. A second electric contact zone 70.2 of the absorber 70 coats the walls of another via passing through the micro-bridge 80 and a connection pillar 54 so as to create an electric contact between the absorber 70 and the connection pillar 54. The first electric contact zone 70.1 participates in thermally coupling the absorber 70 to the diode 5, 6 by thermal conduction.

The absorber 70 advantageously has a resistance substantially equal to the impedance of a vacuum, namely 377Ω/□. It can comprise one or more metallic sublayers of Ti, TIN, NiCr, Al, Au, W, Cu, AlCu, etc. The absorber 70 is for example a layer made of titanium nitride (TiN) with a thickness between 3 nm and 50 nm, preferably between 3 nm and nm. Advantageously, when the thickness of the absorber 70 is less than its skin thickness for a wavelength of the electromagnetic radiation to be detected, the absorber 70 forms with the reflector 20 an optical cavity of the quarter-wave type for this wavelength, so as to reinforce the absorption of the electromagnetic radiation by the absorber 70.

The absorber 70 extends here substantially over the entire upper face of the micro-bridge 80 in order to maximize the quantity of the electromagnetic radiation absorbed. The absorber 70 has an impedance adapted to that of a vacuum. It therefore transmits partially in the far infrared. To increase its absorption, and thus decrease the NEP of the thermal detector 1, it forms with the reflector 20 an optical cavity of the quarter-wave type for a wavelength in the LWIR range. For more compactness and to simplify the design of the thermal detector 1, the diode 5, 6 is arranged inside the optical cavity. The absorber 70 completely covers the diode 5, 6.

Means of the thermal detector 1 prevent the diode 5, 6 from absorbing a quantity of electromagnetic radiation capable of inducing a photo-generated electric current greater than the dark current I_{dark}. The micro-bridge 80 can for example incorporate an absorbant portion facing the diode 5, 6, or the absorber 70 can have a thicker portion facing the diode 5, 6. In this example, the gap energy of the defective region 110 is strictly greater than the energy of the most energetic photon of the electromagnetic radiation. Thus, the electromagnetic radiation does not generate any electric charge carriers by photon absorption in the space charge zone of the diode 5, 6 and no photocurrent is generated. Silicon, germanium and silicon-germanium satisfy this condition in the far infrared range. The electromagnetic radiation to be detected can come from a scene to be observed, optionally filtered by filters and/or by the materials of optical elements used to image the scene, for example such as lenses.

The thermal detector 1 further comprises a lower encapsulation 82 and an upper encapsulation 84. The lower encapsulation 82 extends over a lower face of the micro-bridge 80, over the entirety thereof, and between the micro-bridge 80 and the diode 5, 6. The lower encapsulation 82 further covers the lateral sides of the diode 5, 6 and an entire lower face of the diode 5, 6 opposite to the micro-bridge 80. The upper encapsulation 84 entirely covers the absorber 70 on one side thereof opposite to the micro-bridge 80, as well as the lateral sides of the micro-bridge 80. The lower 82 and upper 84 encapsulations can for example be protective layers resistant to the etching of the sacrificial material. A connection pillar 54 passes completely through the lower encapsulation 82 facing the anode 101.1, so as to electrically connect the anode 101.1 to the readout circuit 12 via the corresponding connection pillar 54, thermal insulation arm 60 and anchoring pillar 52. The cathode 105 is electrically connected to the readout circuit 12 via the first and second electric contact zones 70.1, 70.2 and a portion of the absorber 70 connecting them, as well as via a corresponding connection pillar 54, thermal insulation arm 60 and anchoring pillar 52. The first electric contact zone 70.1 is advantageously in contact with a siliconized zone of the cathode 105 comprising NiSi, CoSi or PtSi, in order to create an ohmic contact having low electric resistance. The anode connection pillar 54 is advantageously in contact with a siliconized zone of the anode 101.1 comprising NiGe, or TiGe, in order to create an ohmic contact having low electric resistance.

During operation, the readout circuit 12 reverse biases the diode 5, 6 to a bias voltage Vd equal to the difference in electric potentials between the anode 101.1 and the cathode 105. The bias voltage Vd is sufficient in absolute value to extend a space charge zone of the diode 5, 6 until it reaches the defective region 110. The bias voltage Vd is insufficient in absolute value to generate a phenomenon of impact ionization in the diode 5, 6, that is to say that the bias voltage Vd is strictly lower than a breakdown voltage in absolute value of the diode 5, 6. Free electrons and/or holes are generated by thermal stirring from or via inter-gap energy levels created by the defects of the defective region 110, and optionally by non-activated dopant atoms of the charge layer 102. Since the defective region 110 is in the space charge zone, just like the charge layer 102, the internal electric field is sufficient at their levels to collect the thermally generated electrons and holes, respectively at the cathode 105 and at the anode 101.1 of the diode 5, 6. Thus, a dark current I_{dark} passes through the diode 5, 6. The latter is read by the readout circuit 12.

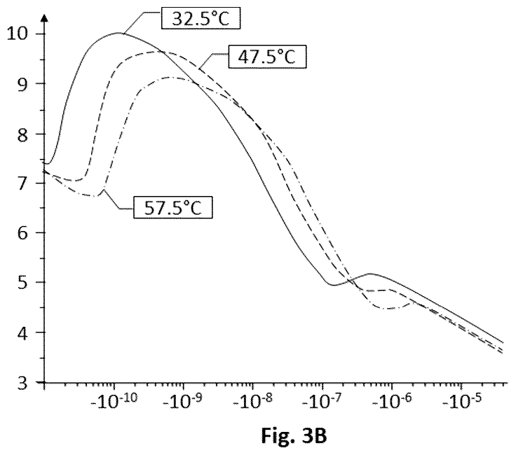

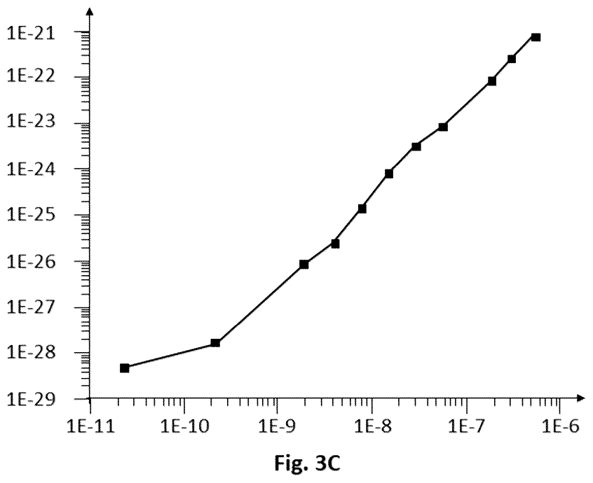

FIGS. 3A to 3C are measurement results obtained with a diode 5 according to the first example. The diode 5 has a cylindrical upper part having a diameter equal to 40 μm, consisting of the small-gap 101, charge 102, spacer 103 and transition 104 layers. The cylindrical part rests on the cathode 105. The cathode 105 is exposed on a peripheral part of the diode 5 on which an electric contact allowing to electrically contact it on the same side as the anode 101.1 rests.

The cathode 105 and the charge 102, spacer 103 and transition 104 layers are made of silicon. The small-gap layer 101 is made of germanium. The defective region 110 was generated by an epitaxy of the small-gap layer 101 on the charge layer 102. The defects of the defective region 110 are therefore substantially dislocations. The difference in lattice parameters between the germanium and the silicon is 4.2%. A density of dislocations in the defective region 110 of approximately 10⁷ dislocations/cm² was observed.

The thicknesses of the small-gap 101, filler 102, spacer 103, and transition 104 layers are equal to 1 μm, 0.08 μm, 1 μm and 0.1 μm, respectively. The cathode 105 has a thickness equal to 0.4 μm. The concentrations of dopant atoms in the small-gap 101, charge 102, spacer 103, and transition 104 layers are respectively equal to 1E16 atoms/cm², 1.6E17 atoms/cm², 1E15 atoms/cm² and 1E17 atoms/cm². The concentration of dopant atoms in the cathode 105 is equal to 1E19 atoms/cm². The small-gap 101, filler 102 and spacer 103 layers are P-doped. The transition layer 104 and the cathode 105 are N-doped.

FIG. 3A gives the measured value of the TCC in % as a function of the bias voltage Vd in volts, for three temperatures of the diode 5 marked by a box (32.5° C., 47.5° C. and 57.5° C.). The TCC is calculated from the value of the dark current measured according to the formula

$$TCC = \frac{1}{{I}_{dark}} \frac{{dI}_{dark}}{dT} .$$

It is observed that the TCC has a maximum peak between −11V and −7V. In this range of bias voltages, the TCC is greater than 7.5% and reaches a maximum of 10% for a temperature of the diode 5 equal to 32.5° C. The TCC increases between −2V and −1V for an operating mode dominated by the diffusion of electric charge carriers in the silicon, leading to very low electric current values.

When Vd decreases (increases in absolute value), the width of the space charge zone, measured perpendicularly to the main plane of the diode 5, increases. It extends from the transition layer 104 towards the intermediate layer 103. Below −7V, the electric field increases in the vicinity of the defective region 110 favoring an SRH electric current from the defective region 110 which leads to a sudden increase in the dark current I_{dark} (the absolute value of the slope of the dark current as a function of the bias voltage thus increases from 0.036 nA/V to 3.96 nA/V when the bias voltage Vd decreases). This SRH electric current is greater when the gap energy of the defective region 110 is low and the number of defects thereof is high. The dark current continues to increase as long as the bias voltage decreases, with a smaller slope below −11V, until the avalanche voltage of the diode 5 is reached, below −30V.

In the optimal range of bias voltages Vd, between −11V and −7V, the difference in gap energy between the charge layer 102 and the defective region 110, and the distribution of the internal electric field of the diode 5 are such that a high variability of the SRH electric current as a function of the temperature is obtained (even higher when the respective gap energies of the charge layer 102 and of the defective region 110 are high) and a sufficiently high SRH electric current is read by the readout circuit 12 (even higher when the gap energy of the defective region 110 is low or its number of defects is high). The concentrations of dopant atoms in the charge 102 and spacer 103 layers, as well as their respective thicknesses, are such that no phenomenon of impact ionization occurs in the diode 5, in particular in the spacer layer 103 and in the small-gap layer 101, when the thermal detector 1 is in operation. This allows to minimize the reading noise, in particular the 1/f noise. The avalanche voltage of the diode 5 is less than −30V here.

FIG. 3B gives the measured value of the TCC in % as a function of the dark current I_{dark} in amperes, for the same three temperatures as those of FIG. 3A (32.5° C., 47.5° C. and 57.5° C.). It is observed that the TCC peaks identified in FIG. 3A are reached for dark currents I_{dark} between 0.1 nA and 10 nA, which are adapted to a readout circuit 12 of a thermal image sensor of the global shutter type.

A thermal image sensor of the global shutter type generally comprises several thermal detectors arranged in an array. Each thermal detector corresponds to one pixel of the image. A readout circuit common to all the pixels simultaneously reads the signals generated by all the pixels. When each signal is an electric current, the latter stores electric charges in one storage capacitor per pixel. The voltage at the terminals of the storage capacitor is characteristic of the intensity of the electromagnetic radiation absorbed by the corresponding thermal detector. This voltage is read by the common readout circuit, optionally by comparison to a reference voltage. Since there are as many storage capacitors as pixels, the footprint thereof, and thus their storage capacity, should be limited, without however compromising the signal-to-noise ratio of the signal read by the common readout circuit. For this purpose, it is often accepted that an electric current generated by thermal detectors between 0.1 nA and 10 nA is a good compromise.

The thermal detector 1 according to the invention can also be suitable for other types of thermal image sensors, such as sensors of the rolling shutter type. For this type of sensor, the signals coming from the array of thermal detectors are read line by line, or column by column. The electric current read by the common readout circuit, coming from each pixel, can in this case be greater than 10 nA and can reach several μA.

In FIG. 3B, the dark currents generated at the peaks of TCC increase with the temperature of the diode 5, while the distribution of the internal electric field remains substantially unchanged (few variations in the bias voltage Vd at the peaks of TCC as a function of the temperature in FIG. 3A). The hypothesis is put forth that the size of the offset depends on the difference in gap energies between the charge layer 102 and the defective region 110 (change in the relative proportion of the contributions of the charge layer 102 and of the defective region 110 to the dark current I_{dark}, as a function of the temperature).

FIG. 3C gives the power spectral density of the noise of the diode 5 of FIG. 3A at 10 Hz (axis of the ordinates in A²/Hz), as a function of the dark current I_{dark} (axis of the abscissae in amperes). The power spectral density (or PSD) was measured for a temperature of the diode 5 equal to 30° C.

It is observed that the PSD remains lower than 3E-25A²/Hz in the range of dark currents I_{dark} between 0.1 nA and 10 nA. This noise level at 10 Hz is lower than that of most thermal transducers of the prior art, in particular those operating with a forward-biased thermometer diode. This low noise level allows to obtain an NEP of the thermal detector reduced with respect to the prior art.

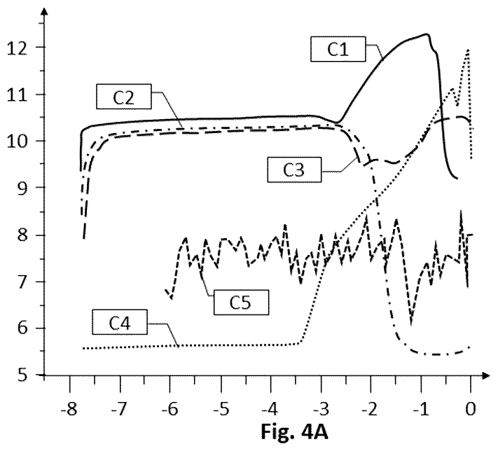

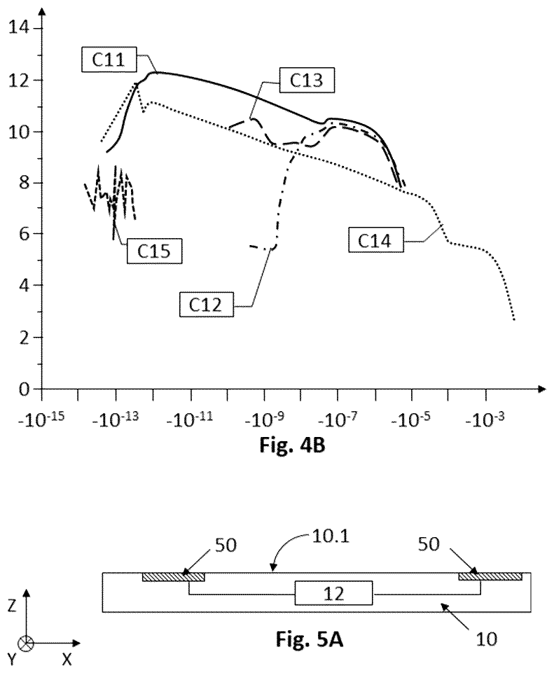

FIGS. 4A and 4B give results similar to FIGS. 3A and 3B, but this time obtained by simulation, for various types of materials. FIG. 4A gives the value of the TCC in % at 32.5° C., as a function of the bias voltage Vd in volts. FIG. 4B gives these values of the TCC in %, as a function of the dark current I_{dark} in amperes. All the curves were obtained with the same density of dislocations in the defective region 110, equal to 10⁷ dislocations/cm².

The diode 5 is a diode according to the first example, devoid of a structured interface 101.5. The thicknesses of its constituent layers are the same for all the curves, and less than those of the corresponding layers of the diode 5 of FIGS. 3A to 3C. The diode 5 is a rectangular parallelepiped having a square cross-section with 10 μm sides. It therefore has a much lower volume than that of FIGS. 3A to 3C, and therefore a lower thermal capacity allowing to reduce the response time of the thermal detector 1. The concentrations of dopant atoms in the constituent layers of the diode 5 are identical for all the curves.

For each curve, the thicknesses of the small-gap 101, charge 102, spacer 103, and transition 104 layers are equal to 0.1 μm, 0.05 μm, 0.1 μm and 0.05 μm, respectively. The cathode 105 has a thickness equal to 0.05 μm. The concentrations of dopant atoms in the small-gap 101, charge 102, spacer 103, and transition 104 layers are respectively equal to 1E16 atoms/cm², 2E17 atoms/cm², 1E15 atoms/cm² and 5E17 atoms/cm². The concentration of dopant atoms in the cathode 105 is equal to 1E19 atoms/cm². The small-gap 101, filler 102 and spacer 103 layers are P-doped. The transition layer 104 and the cathode 105 are N-doped.

below gives the materials of the layers for each curve. The reference number of the layer is given in the first line, thus the materials of the cathode 105 are given in the last column of. The references of the curves are given in the first column, thus the last line gives the materials of the curve C5 of FIG. 4A, and of the curve C15 of FIG. 4B. The materials are given by their chemical symbols, thus “Ge” is germanium.

TABLE 1

| | 101 | 102 | 103 | 104 | 105 |
|---|---|---|---|---|---|
| C1, | Ge | Si | Si | Si | Si |
| C11 | | | | | |
| C2, | Ge | Si | Ge | Si | Si |
| C12 | | | | | |
| C3, | Ge | Ge | Si | Si | Si |
| C13 | | | | | |
| C4, | In_{0.53}Ga_{0.47}As | Si | Si | Si | Si |
| C14 | | | | | |
| C5, | GaN | Si | Si | Si | Si |
| C15 | | | | | |

The TCC peak in the case of a defective region 110 made of germanium and a charge layer 102 made of silicon is preserved after a decrease in the volume of the diode 5 (comparison of FIGS. 3A and 4A). The TCC peak occurs around 1.5E-3 nA. It is greater than 10.6% in the dark current range between 0.1 nA and 10 nA (FIG. 4B). The TCC is between 10% and 12%, for a bias voltage Vd between −1V and −2.5V and a dark current between 0.1 pA and 0.1 μA. It is thus possible to obtain a good TCC with a diode 5 having a reduced thermal capacity, the dimensions of which are also compatible with pixels having a size less than or equal to 12 μm, or even less than or equal to 10 μm. It should be noted that the gap energy of germanium is equal to 0.66 eV, that of silicon is equal to 1.12 eV, which gives a difference in gap energies between the charge layer 102 and the defective region 110 equal to 0.46 eV.

It is observed that, when the gap energies of the charge layer 102 and of the defective region 110 are equal (curves C3 and C13), the TCC does not comprise a peak. For a defective region 110 made of In_{0.53}Ga_{0.47}As and a charge layer 102 made of silicon (curves C4 and C14), the TCC is between 9% and 10.1% in the dark current range between 0.1 nA and 10 nA. The gap energies of In_{0.53}Ga_{0.47}As and of silicon are respectively equal to 0.74 eV and 1.12 eV, or a difference in gap energies between the charge layer 102 and the defective region 110 equal to 0.38 eV.

When the gap energy of the defective region 110 is greater than the gap energy of the charge layer 102 (curves C5 and C15), the TCC is below 8.5%. It is difficult to control. Furthermore, the electric current is very low (dark current less than 1E-3 nA), insufficient to be able to be read by the readout circuit 12 without excessive electronic noise.

In the dark current range between 0.1 μA and 10 μA, a good TCC is obtained, greater than or equal to 10%, for the curves C11, C12 and C13. In the diode 5 corresponding to the curves C2 and C12, the gap energy of the spacer layer 103 is equal to the gap energy of the defective region 110.

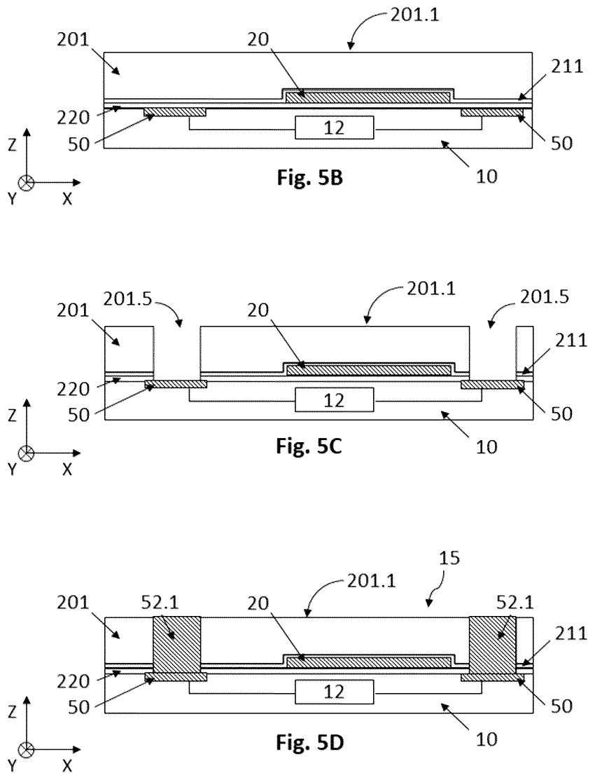

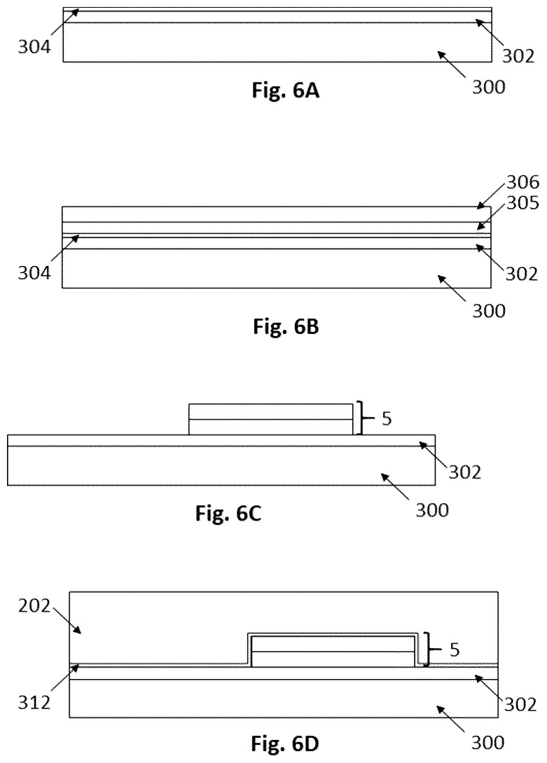

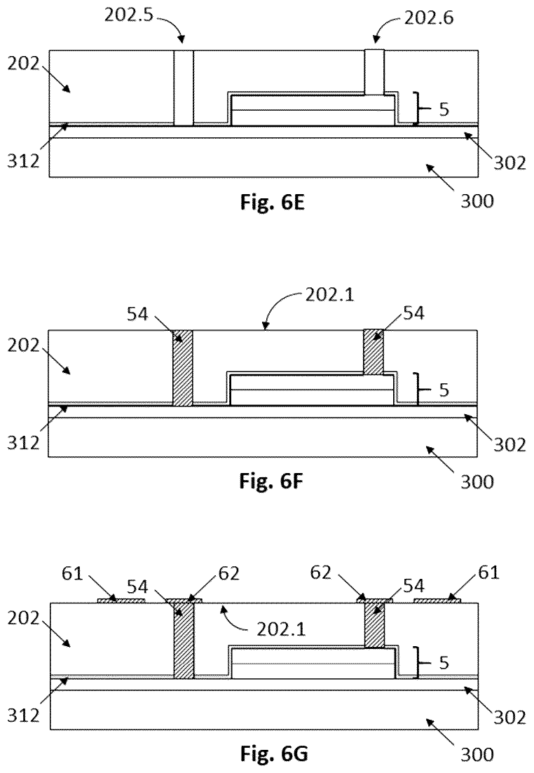

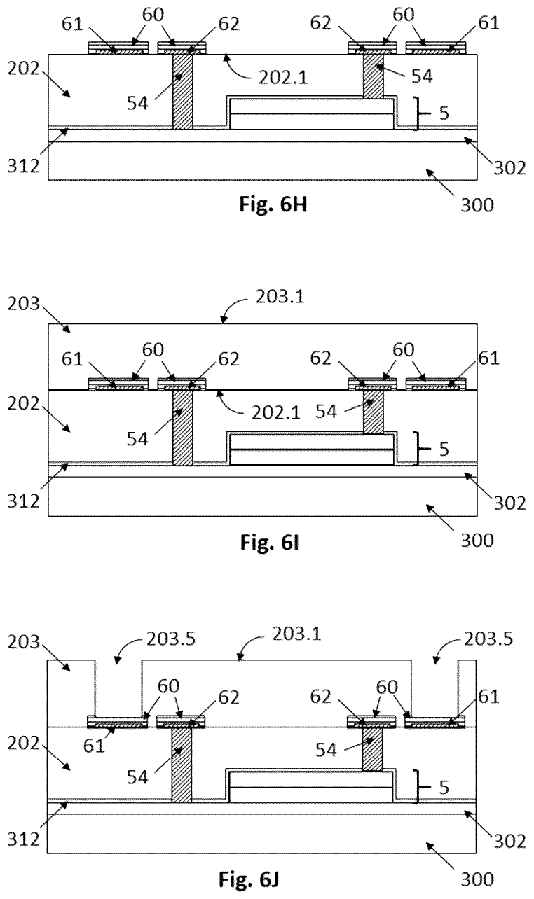

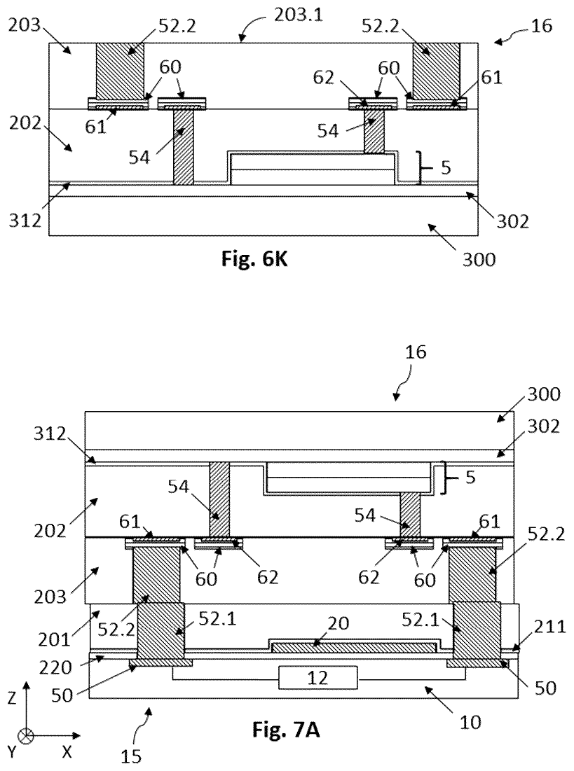

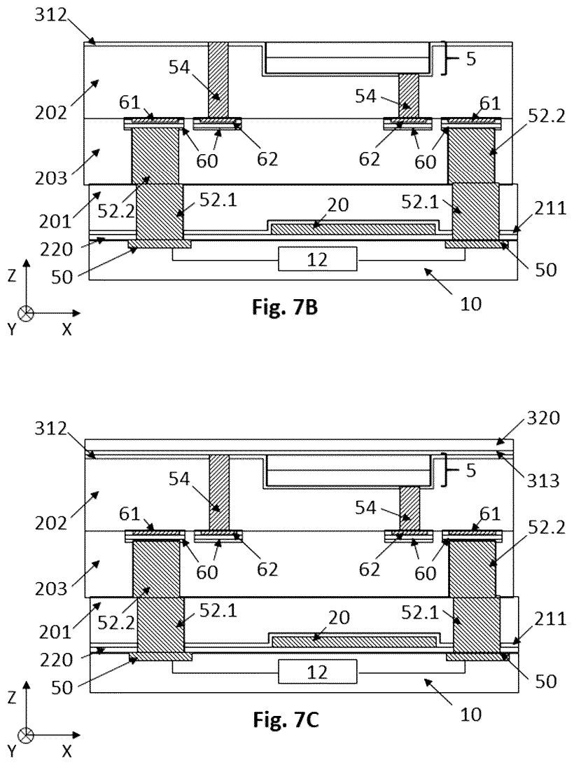

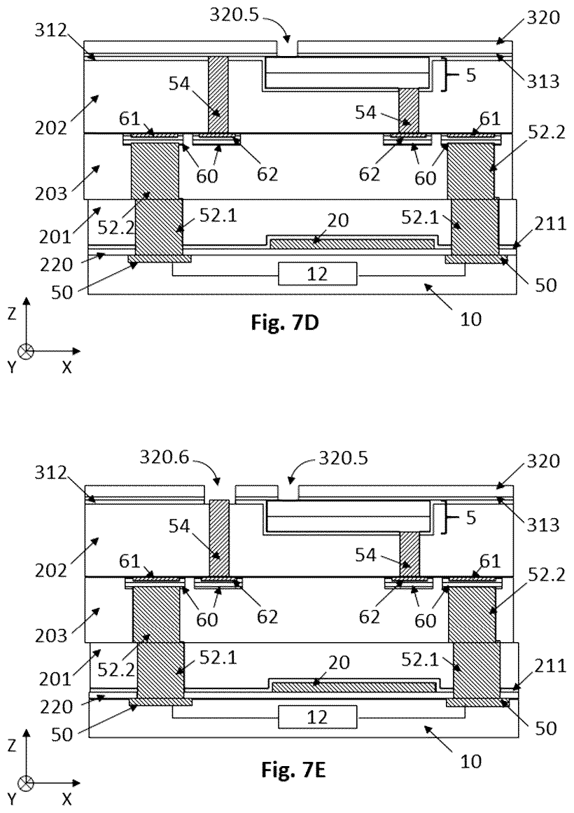

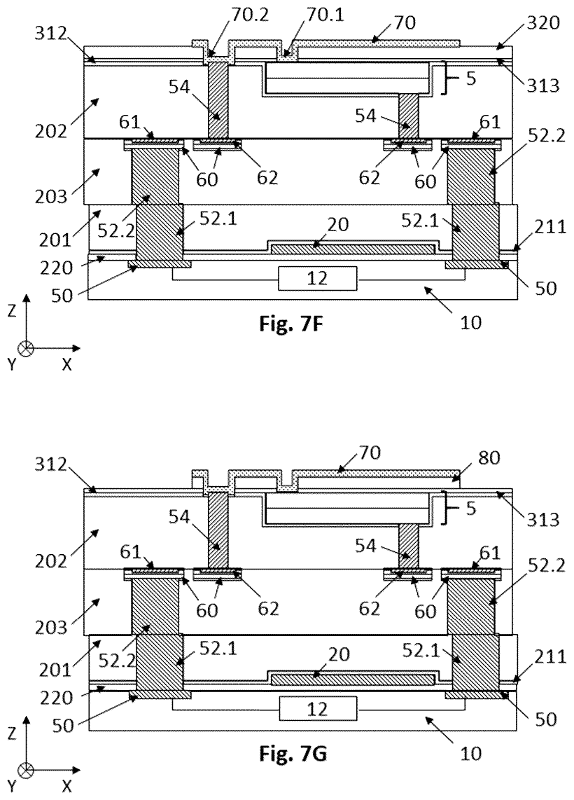

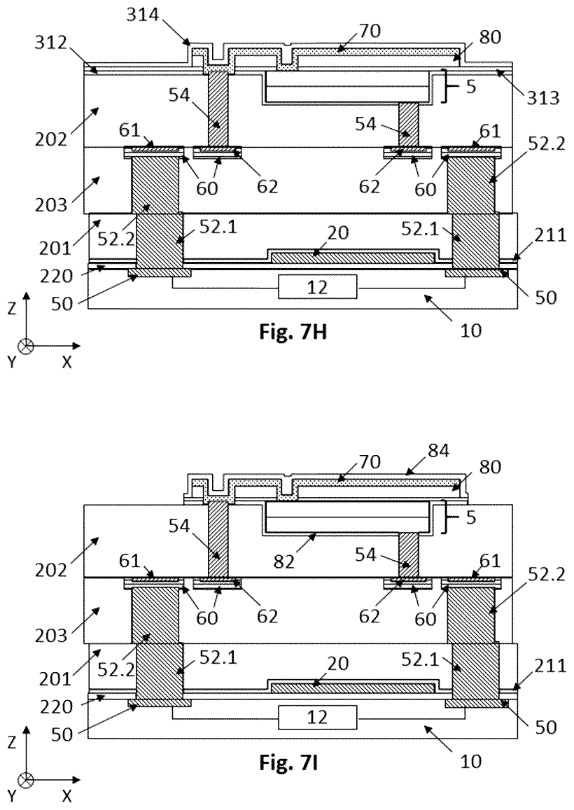

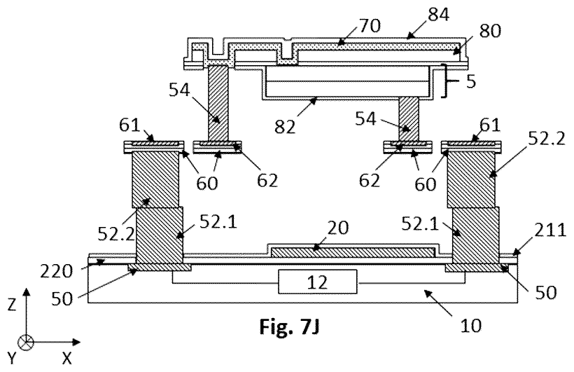

An example of a method for manufacturing a thermal detector 1 as illustrated in FIG. 2 is now described in connection to FIGS. 5A to 5D, 6A to 6K and 7A to 7J. FIGS. 5A to 5D are schematic cross-sectional views of steps for manufacturing a first part 15 of the thermal detector 1. FIGS. 6A to 6K are schematic cross-sectional views of step for manufacturing a second part 16 of the thermal detector 1. The first and second parts 15, 16 are assembled in FIG. 7A. FIGS. 7A to 7J are schematic cross-sectional views of final steps of the manufacturing method. In these views, some elements may have been omitted to avoid overloading the diagrams. Elements shown in the cutting plane can be located in the foreground or in the background without going beyond the scope of the invention, for example such as anchoring or connection pillars. This example of a manufacturing method will be described in connection to a particular combination of conductivities associated with the doped layers, with it being understood that the manufacturing method can easily be adapted to cover all the conductivity combinations possible in a thermal detector 1 according to the invention.

In FIG. 5A, a readout substrate 10 comprising a readout circuit 12 is provided. The readout circuit 12 comprises connection pads 50 flush with an upper face 10.1 of the readout substrate 10. Here, two connection pads 50 are shown. The connection pads 50 are made of an electrically conductive material, for example made of metal such as an aluminum-copper alloy (AICu).

In FIG. 5B, a spacer layer 220 is deposited on the upper face 10.1 of the readout substrate 10 and on the connection pads 50. The spacer layer 220 extends substantially over the entire upper face 10.1. It is made of a dielectric material, here silicon oxide. The spacer layer 220 has for example a thickness of 50 nm. It can be a layer for passivating and/or protecting the readout substrate 10.

A reflector 20 resting on the spacer layer 220 is then formed, so as to be in contact with the latter. For this, a metal layer is deposited on the spacer layer 220, here made of AlCu. The metal layer has for example a thickness equal to 400 nm. It is etched locally all the way through. The reflector 20 is formed by a remaining part of the metal layer not covering the connection pads 50.

A first protective layer 211 is then deposited conformally, on the spacer layer 220 and the reflector 20. The first protective layer 211 is here made of a material resistant to etching with hydrofluoric acid (HF) in the vapor phase, for example made of amorphous silicon. In this example, the thickness of the first protective layer 211 is less than that of the reflector 20.

A first sacrificial layer 201 is then formed on the first protective layer 211. The first sacrificial layer 201 is made of a sacrificial material that can be etched selectively with respect to the first protective layer 211. In this example, it is made of silicon oxide. In this case, it can be obtained by a deposition via CVD with TEOS as the precursor gas. The first sacrificial layer 201 can also be made of polyimide.

The first sacrificial layer 201 is polished by chemical mechanical polishing (or CMP) so as to obtain an upper face 201.1 of the first sacrificial layer 201 flat and parallel to the plane (X, Y). Its thickness measured parallel to the axis Z away from the reflector 20 is strictly greater than the thickness of the reflector 20. Here it has a thickness equal to 950 nm.

In FIG. 5C, through-openings 201.5 are etched in the first sacrificial layer 201 opposite each connection pad 50. Each through-opening 201.5 passes all the way through the first sacrificial layer 201, the first protective layer 211 and the spacer layer 220. The bottom of each through-opening 201.5 consists of a part of a connection pad 50.

In FIG. 5D, a base 52.1 of an anchoring pillar 52 is formed in each through-opening 201.5. For this, the through-openings 201.5 are entirely filled with metal by a damascene process known from the prior art. Each base 52.1 is flush with the upper face 201.1 of the first sacrificial layer 201. Here it is made of copper, optionally covered with a metal coating. At the end of FIG. 5D, the first part 15 of the thermal detector 1 is obtained.

In FIG. 6A, a wafer of the semiconductor on insulator type is provided. It comprises a sacrificial substrate 300, a dielectric layer 302, and a growth layer 304 made of a crystalline semiconductor material, preferably the second material. Here this is a silicon-on-insulator (or SOI) wafer for which the sacrificial substrate 300 is made of silicon, the dielectric layer 302 is made of silicon oxide and the growth layer 304 is made of crystalline silicon.

In this example of a method, the growth layer 304 is intended to house the cathode 105. In this step, it is N-doped, for example by implantation of phosphorus atoms, preferably throughout its entire volume. The concentration of dopant atoms is equal to that expected in the cathode 105. A doped portion of the growth layer 304 is intended to be the cathode 105. In an alternative manufacturing method, the growth layer 304 can be intended to house the anode 101.1. In this case, a P-type doping of the growth layer 304 is carried out.

In FIG. 6B, an epitaxial growth of a second layer 305 of the second material on the growth layer 304 is carried out, followed by an epitaxial growth of a first layer 306 of the first material on the second layer 305. A difference in lattice parameters and/or a difference in coefficients of thermal expansion between the first and the second materials are capable of generating a defective sublayer of the first layer 306 comprising dislocations, preferably 10⁵ and 10¹² dislocations per cm². The defective sublayer is intended to house the defective region 110.

The defective sublayer can comprise other types of crystalline defects during the epitaxy in addition to or instead of the dislocations, such as grain joints, impurities. Defects can be created after the epitaxy by ion implantation. A sub-step of surface treatment of the second layer 305 can be provided before the epitaxy of the first layer to promote the formation of dislocations, for example such as surface texturing by chemical or mechanical etching to create a surface roughness.

The second layer 305 here has a gap energy strictly greater than a gap energy of the first layer 306, called small-gap layer 306. In contrast, the second layer 305 is hereinafter called large-gap layer 305. The large-gap layer 305 is intended to house, in the order of appearance during the growth, the transition layer 104, the spacer layer 103 and the charge layer 102. One or more in-situ dopings are carried out in the epitaxy equipment to obtain the doping concentrations respectively expected in these layers. The small-gap layer 306 is intended to house the small-gap layer 101 with its defective region 110 in a part of the defective sublayer, preferably unintentionally doped. The epitaxy of the small-gap layer 306 can end with in-situ boron doping to create the anode 101.1. A structuring of the large-gap layer 305 by one or more photolithography and etching steps can be carried out before the epitaxy of the small-gap layer 306 to obtain a diode 6 according to the second example.

The thickness of the large-gap layer 305 is equal to the cumulative thicknesses of the transition 104, intermediate 103 and charge 102 layers. The thickness of the growth layer 304 is equal to the thickness of the cathode 105. And the thickness of the small-gap layer 306 is equal to the thickness of the small-gap layer 101.

In this example, the large-gap layer 305 is made of silicon and the small-gap layer 306 is made of germanium. In this case, the small-gap layer 306 made of germanium is preferably protected from oxidation by a thin crystalline layer made of silicon (not shown), having a thickness less than or equal to its critical thickness, for example equal to 5 nm. The thin layer made of silicon is preferably epitaxied following the epitaxy of the small-gap layer 306 made of germanium, without venting, for example in the same epitaxy equipment.

In FIG. 6C, the small-gap 306, large-gap 305 and growth 304 layer are etched locally all the way through to the dimensions of the diode 5. In FIG. 6C and following, the growth layer 304 is not shown since it is made here of the same material as the large-gap layer 305 and in one piece with the latter (no visible interface). If the small-gap layer 306 has not been doped during the epitaxy in a region of this layer intended to be the anode 101.1, it can be doped by implantation during the step of FIG. 6C, before or after the etching. The implantation can optionally be local.

In FIG. 6D, a second protective layer 312 is conformally deposited on the dielectric layer 302 and the diode 5. A second sacrificial layer 202 is then deposited on the second protective layer 312. The second sacrificial layer 202 is made of the same sacrificial material as the first sacrificial layer 201, here made of silicon oxide. This can be CVD deposition using TEOS followed by CMP polishing. The thickness of the second sacrificial layer 202 determines the distance between the thermal insulation arms 60 and the micro-bridge 80. The second sacrificial layer 202 here has a thickness equal to 1 μm.

In FIG. 6E, a through-opening 202.5 is etched passing all the way through the second sacrificial layer 202 and the second protective layer 312 in a region inside which they are in contact, until it reaches the dielectric layer 302 without going beyond it. A through-opening 202.6 is etched facing the anode 101.1, passing all the way through the second sacrificial layer 202 and the second protective layer 312 until it reaches the anode 101.1, without going beyond it.

In FIG. 6F, the through-openings 202.5 and 202.6 are completely filled with metal to form connection pillars 54 in each of the through-openings 202.5 and 202.6. The connection pillars 54 are for example made of tungsten (W) coated with a Ti/TiN bilayer. They are flush with a free face 202.1 of the second sacrificial layer 202, opposite to the sacrificial substrate 300. The free face 202.1 is substantially flat.

In FIG. 6G, connection heads 62 are formed on and in contact with each of the connection pillars 54. Each connection head 62 extends locally on the free face 202.1, parallel to it. It completely covers the corresponding connection pillar 54. The connection heads 62 are metallic, here made of TiN.

Optional pads 61 extending on the free face 202.1 of the first sacrificial layer 201 are formed subsequently or simultaneously. The pads 61 are made of an electrically conductive material, for example metal, here TiN. The pads 61 and the connection heads 62 here have the same height measured perpendicularly to the free face 202.1.

In FIG. 6H, the thermal insulation arms 60 are formed. For this, a first electrically insulating layer is deposited on the free face 202.1, the pads 61 and the connection heads 62. An opening is made passing all the way through the first electrically insulating layer facing each connection head 62. A metal layer is deposited conformally on the first electrically insulating layer and in the openings, in contact with the connection heads 62. The metal layer is separated from each pad 61 by a portion of the first electrically insulating layer. A second electrically insulating layer is deposited on the metal layer. The stack consisting of the first electrically insulating layer, the metal layer and the second electrically insulating layer is etched locally all the way through to obtain two thermal insulation arms 60 in the desired shape.

Each thermal insulation arm 60 extends on the free face 202.1 from a connection head 62 to a pad 61. The metal layer is for example made of TiN. The first and second electrically insulating layers are here made of a material resistant to hydrofluoric acid. They can be made of a dielectric material such as silicon nitride or made of amorphous silicon.

In FIG. 6I, a third sacrificial layer 203 is deposited on the free face 202.1 of the second sacrificial layer 202 and on the thermal insulation arms 60. The third sacrificial layer 203 is made of the same sacrificial material as the first and second sacrificial layers 201, 202, here made of silicon oxide. This can be CVD deposition using TEOS followed by CMP polishing. The third sacrificial layer 203 has a flat free face 203.1 opposite to the second sacrificial layer 202. The cumulative thickness of the first, second and third sacrificial layers 201, 202, 203 determines a height of a quarter-wave cavity for a wavelength of the electromagnetic radiation, formed between the reflector 20 and the absorber 70.

In FIG. 6J, a through-opening 203.5 is etched facing each pad 61, passing all the way through the third sacrificial layer 203 and a part of a thermal insulation arm 60, until it reaches an electrically conductive part of the thermal insulation arm 60, here a remaining part of the metal layer made of TiN deposited during the step of FIG. 6I.

In FIG. 6K, each through-opening 203.5 is completely filled with metal to obtain a top 52.2 of an anchoring pillar 52 facing each pad 61. The tops 52.2 are for example obtained by a damascene process comprising an electrochemical deposition of copper. The tops 52.2 are flush with the free face 203.1 of the third sacrificial layer 203. At the end of FIG. 6K, the second part 16 of the thermal detector 1 is obtained.

In FIG. 7A, the second part 16 is transferred onto the first part 15 by direct hybrid bonding. For this, the free face 203.1 of the third sacrificial layer 203 is placed in contact with the upper face 201.1 of the first sacrificial layer 201, and each top 52.2 with a base 52.1. Each top 52.2 preferably has a cross-section substantially identical to the cross-section of the corresponding base 52.1 in a plane defined by the bonding interface separating the upper face 201.1 from the free face 203.1. In FIG. 7A, the second part 16 is shown with a slight misalignment with respect to the first part 15 which can result from an alignment uncertainty inherent to the method. At the end of FIG. 7A, each base 52.1/top 52.2 pair constitutes an anchoring pillar 52 of the thermal detector 1.

In FIG. 7B, the sacrificial substrate 300 and the dielectric layer 302 are removed to expose the cathode 105, the second protective layer 312 and a cathode connection pillar 54 intended to be electrically connected to the cathode 105. For this, the majority or the entirety of the sacrificial substrate 300 can be lapped, optionally followed by steps of polishing and/or chemical etching of a remaining part of the sacrificial substrate 300. The dielectric layer 302 is removed by wet chemical etching selective with respect to the second protective layer 312 and the cathode 105. For this, they are advantageously both made of the same material, here made of silicon.

In FIG. 7C, a third protective layer 313 is deposited on the cathode connection pillar 54, the cathode 105 and the second protective layer 312, so as to completely cover the second protective layer 312 and the diode 5. The third protective layer 313 is made of a material resistant to an etching of the first, second and third sacrificial layers 201, 202, 203, here made of amorphous silicon or alumina. The second and third protective layers 312, 313 together cover the diode 5 on all sides, except for a part of the anode 101.1 in contact with the connection pillar 54 connecting it, called the anode connection pillar 54.

An upper dielectric layer 320 is then deposited on the third protective layer 313. The upper dielectric layer 320 is made of any dielectric material. Here it is made of silicon oxide. A portion of the upper dielectric layer 320 facing the diode 5 is intended to be the micro-bridge 80 of the thermal detector 1. The cumulative thickness of this portion and of the second and third protective layers 312, 313 measured perpendicularly to the axis Z is sufficient to ensure a good mechanical strength of the micro-aboard 80. The thermal conduction between the absorber 70 and the diode 5 increases when the thickness of the third protective layer 313 and/or of the upper dielectric layer 320 decreases. The second and third protective layers 312, 313 and the upper dielectric layer 320 have here thicknesses equal to 10 nm, 10 nm, and 200 nm, respectively.

In FIG. 7D, a first via 320.5 passing all the way through the upper dielectric layer 320 and the third protective layer 313 is etched facing the cathode 105, without going beyond it. At the end of this step, the cathode 105 is exposed at a bottom of the first via 320.5.

In FIG. 7E, a second via 320.6 passing all the way through the upper dielectric layer 320 and the third protective layer 313 is etched facing the cathode connection pillar 54. At the end of this step, the cathode connection pillar 54 is exposed at a bottom of the second via 320.6.

In FIG. 7F, the absorber 70 is formed. For this, a metal layer is deposited conformally on the upper dielectric layer 320 and in the first and second vias 320.5, 320.6. This metal layer conforms to the sides and the bottom of the first and second vias 320.5, 320.6. The metal layer is then etched locally all the way through to obtain the absorber 70 with the desired dimensions.

The absorber 70 comprises a first electric contact zone 70.1 in physical contact with the cathode 105 and coating the walls and the bottom of the first via 320.5. It comprises a second electric contact zone 70.2 in physical contact with the cathode connection pillar 54 and coating the walls and the bottom of the second via 320.6. A portion of the absorber 70 connects the first and second electric contact zones 70.1, 70.2 allowing to electrically connect the cathode 105 to the cathode connection pillar 54 and to the readout circuit 12.

In FIG. 7G, the upper dielectric layer 320 is etched locally all the way through in a region of the thermal detector 1 surrounding the diode 5 and the connection pillars 54 in a top view, to obtain the micro-bridge 80. In this example, the micro-bridge 80 and the absorber 70 have cross-sections that coincide in a top view, without this being indispensable.

In FIG. 7H, a fourth protective layer 314 is conformally deposited on the third protective layer 313 and on the absorber 70. The fourth protective layer 314 completely covers the absorber 70 and the micro-bridge 80, in particular on its lateral sides. The fourth protective layer 314 is made of a material resistant to the etching of the sacrificial material, here made of amorphous silicon or alumina.

In FIG. 7I, the second, third and fourth protective layers 314 are etched locally all the way through in a region of the thermal detector 1 surrounding the diode 5, the absorber 70, the micro-bridge 80 in a top view, inside which the third protective layer 313 is in contact with the second protective layer 312 and the fourth protective layer 314.

In FIG. 7J, the first, second and third sacrificial layers 201, 202, 203 are removed selectively with respect to the first, second, third, and fourth protective layers 211, 312, 313, 314, and with respect to the thermal insulation arms 60, the anchoring 52 and connection 54 pillars. These three sacrificial layers are removed here by etching with hydrofluoric acid in vapor phase. Alternatively, it is possible to use sacrificial layers made of polyimide, removed by an oxygen plasma. At the end of FIG. 7J, the thermal detector 1 is obtained.

Specific embodiments have just been described. Various alternatives and modifications will become apparent to a person skilled in the art. It is for example possible to modify the method for manufacturing the second part 16 to dispose the absorber 70 between the diode 5 and the reflector 20 in the thermal detector 1. The thermal insulation arms 60 can be coplanar with the micro-bridge 80. The micro-bridge 80 can be suspended above a cavity made in the readout substrate 10 during the manufacturing of the first part 15.

1. A thermal detector of electromagnetic radiation, comprising:
an absorber configured to heat up by absorption of the electromagnetic radiation,
a thermal transducer comprising a diode thermally coupled to the absorber, the diode comprising a defective region, a spacer layer and a charge layer, all three interposed between an anode and a cathode of the diode, such that:
the charge layer has a concentration of majority carriers at least 100 times greater than a concentration of majority carriers in the spacer layer,
the defective region and the spacer layer are in contact with the charge layer on opposite sides thereof,
the defective region comprises crystalline defects and has a gap energy strictly lower than a gap energy of the charge layer,
the charge layer and the defective region are disposed on the same side of the diode, relative to a junction of the diode;
the thermal detector further comprises a readout circuit configured to:
reverse bias the diode to a bias voltage Vd whose absolute value is strictly lower than the absolute value of the breakdown voltage of the diode, so as to extend a space-charge zone of the diode until it reaches the defective region, and
read a dark current of the diode when it is biased to the bias voltage V_{D}.

2. The thermal detector according to claim 1, wherein the defective region is unintentionally doped.

3. The thermal detector according to claim 1, wherein the diode comprises an unintentionally doped small-gap layer in contact with the charge layer, wherein the defective region and the anode are two separated regions of the small-gap layer, and wherein the defective region comprises dislocations.

4. The thermal detector according to claim 3, wherein the diode comprises a structured interface separating the charge layer from the small-gap layer, so as to confine the dislocations.

5. The thermal detector according to claim 3, wherein the defective region comprises a number of dislocations per cm² between 10⁵ and 10₁₂.

6. The thermal detector according to claim 3, wherein the difference between a gap energy of the charge layer and a gap energy of the defective region is greater than 0.38 eV.

7. The thermal detector according to claim 6, wherein the spacer layer and the charge layer are made of silicon, and wherein the small-gap layer is made of germanium or an alloy of silicon and germanium.

8. The thermal detector according to claim 3, wherein the concentration of majority carriers in the charge layer and the arrangement of the charge layer are such that no impact ionization occurs in the small-gap layer and in the spacer layer when the diode is biased to the bias voltage Vd.

9. The thermal detector according to claim 1, wherein the readout circuit is arranged in and/or on a readout substrate of the thermal detector, wherein the thermal detector is such that it comprises a micro-bridge suspended above the readout substrate, on which the diode and the absorber are fixed on opposite sides thereof, and wherein the diode is electrically connected to the readout circuit by a portion of the absorber.

10. The thermal detector according to claim 1, comprising a reflector forming with the absorber a quarter-wave optical cavity for the electromagnetic radiation inside which the diode is arranged, wherein the diode is such that the gap energy of the defective region is strictly greater than the energy of the most energetic photon of the electromagnetic radiation.

11. A thermal image sensor comprising an array of thermal detectors according to claim 7, wherein the thermal image sensor is a global-shutter sensor, wherein the readout circuit of each thermal detector is a part of a common readout circuit of the image sensor, and wherein the common readout circuit is configured to read a dark current of each diode between 0.1 nA and 10 nA.

12. A method for manufacturing a thermal detector according to claim 1, comprising a step of forming the defective region by implementing a heteroepitaxy of a first layer on a second layer, respectively made of a first semiconductor material and a second semiconductor material, having different lattice parameters so as to create dislocations in a sublayer of the first layer intended to accommodate the defective region.

13. The manufacturing method according to claim 12, comprising a step of homoepitaxy of the second layer on a growth layer comprising an in-situ doping of a sublayer of the second layer intended to accommodate the charge layer.

14. The manufacturing method according to claim 13, wherein the growth layer is intended to accommodate the cathode or the anode, the manufacturing method comprising a step of doping the growth layer prior to the homoepitaxy step.

15. The manufacturing method according to claim 12, comprising a step of structuring the second layer prior to the heteroepitaxy.
